(19) United States
(12) Patent Application Publication
(10) Pub. No.: US 2013/0161735 A1
(43) Pub. Date: Jun. 27, 2013

(54) TRANSISTOR STRUCTURE AND METHOD FOR PREPARING THE SAME

(71) Applicant: Durga Panda, Boise, ID (US)

(72) Inventor: Durga Panda, Boise, ID (US)

(73) Assignee: NANYA TECHNOLOGY CORPORATION, Kueishan (TW)

(21) Appl. No.: 13/336,814

(22) Filed: Dec. 23, 2011

(51) Int. Cl. H01L 29/78; H01L 21/28

(52) U.S. Cl. 257/330; 438/589; 257/E29.262; 257/E21.19

(57) ABSTRACT

A transistor structure includes a semiconductor substrate; a conductor having a lower block in the semiconductor substrate and an upper block on the semiconductor substrate; a metal layer positioned on the upper block; a cap layer positioned on the metal layer; an upper insulation layer positioned at least on sidewalls of the metal layer and the cap layer; and a lower insulation layer positioned on sidewalls of the upper block of the conductor.

### TECHNICAL FIELD

The present disclosure relates to a transistor structure and method for preparing the same, and more particularly, to a transistor structure with increased sidewall thickness and oxide quality and method for preparing the same.

### BACKGROUND

As semiconductor fabrication technology continues to advance, sizes of electronic devices are reduced, and the size and the channel length of the planar channel transistor 10 as shown in FIG. 1 decrease correspondingly. The planar channel transistor 10 in FIG. 1 has been widely used in integrated circuits; however, the continuous shrinking of the device size and the decreasing channel length of the planar channel transistor 10 results in an undesired interaction between the two doped regions 13 and the carrier channel 15 under the gate oxide layer 17. The result of such a reduction in device size is that the controlling ability of the conductive metal layer 19 on the switching operation of the carrier channel 15 is reduced. Hence, causing the so-called short channel effect, which impedes the functioning of the planar channel transistor 10. To address this problem, researchers developed the so-called recessed channel transistor with a recessed gate sandwiched between the two doped regions and an increased channel length.

FIGS. 2 to 4 illustrate a conventional method for preparing a recessed channel transistor 30. First, a pad oxide layer 36 is formed to cover a semiconductor substrate 31 with a trench isolation structure 33, and an etching mask 37 having a plurality of openings 39 is then formed on the pad oxide layer 36. Subsequently, a dry etching process is performed to remove a portion of the pad oxide layer and the semiconductor substrate 31 under the openings 39 of the etching mask 37 so as to form a plurality of recesses 41 in the semiconductor substrate 31, as shown in FIG. 3.

Referring to FIG. 4, after removing the etching mask 37, a thermal oxidation process is performed to form a dielectric layer 42 on the exposed surface of the semiconductor substrate 31, and recessed gates 43 filling the recesses 41 and gate stacks 45 connecting the recessed gates 43 are formed by deposition process, wherein the gate stack 45 may include conductive polysilicon layer, a tungsten silicide layer and a cap nitride layer. Subsequently, an implanting process is performed to implant dopants into the semiconductor substrate 31 so as to form two doped regions 47 serving as the source and the drain at two sides of the recessed gates 43 in the semiconductor substrate 31.

The recessed channel transistor 30 has shown good data retention time characteristics as compared to the planar channel transistor 10 because of its superiorities in drain-induced barrier lowering (DIBL), sub-threshold slope, and junction leakage. However, there are interface traps of high density at the corners of the recessed gates 43 adjacent to the doped regions 47. In addition, there is a high electrical field between the recessed gates 43 and the doped regions 47, which generates a significant gate induced drain leakage (GIDL) current. In other words, the recessed channel transistor 30 exhibits a significant GIDL current due to the large overlap between the recessed gate 43 and the source/drain regions 47 as compared to the planar channel transistor 10, which exhibits substantially no overlap between the gate 19 and the source/drain regions 13, as shown in FIG. 1.

### SUMMARY

One aspect of the present disclosure provides a transistor structure with increased sidewall thickness and oxide quality and method for preparing the same.

One embodiment of the present disclosure provides a transistor structure comprising a semiconductor substrate; a conductor having a lower block in the semiconductor substrate and an upper block on the semiconductor substrate; a metal layer positioned on the upper block; a cap layer positioned on the metal layer; an upper insulation layer positioned at least on sidewalls of the metal layer and the cap layer; and a lower insulation layer positioned on sidewalls of the upper block of the conductor.

Another aspect of the present disclosure provides a method for preparing a transistor structure, comprising the steps of forming a recess in a semiconductor substrate; forming a first conductive layer on the semiconductor substrate and filling the recess; forming a second conductive layer on the first conductive layer; forming a depression in the first conductive layer and the second conductive layer, wherein the depression comprises a bottom in the first conductive layer; performing an implanting process through the depression to form an implanting region in the first conductive layer under the depression; performing a thermal treating process to form a diffused region adjacent to the implanting region; performing an etching process to remove the implanting region; and performing an oxidation process to convert the diffused region into a lower insulation layer.

The foregoing has outlined rather broadly the features of the present disclosure in order that the detailed description of the invention that follows may be better understood. Additional features of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the invention as set forth in the appended claims.

### BRIEF DESCRIPTION OF THE DRAWINGS

The objectives of the present disclosure will become apparent upon reading the following description and upon reference to the accompanying drawings in which:

FIG. 1 illustrates a planar channel transistor according to the prior art;

FIG. 2 to FIG. 4 illustrate a method for preparing a recessed channel transistor according to the prior art; and

FIG. 5 to FIG. 11 are cross-sectional views showing a method for preparing a transistor structure according to one embodiment of the present disclosure.

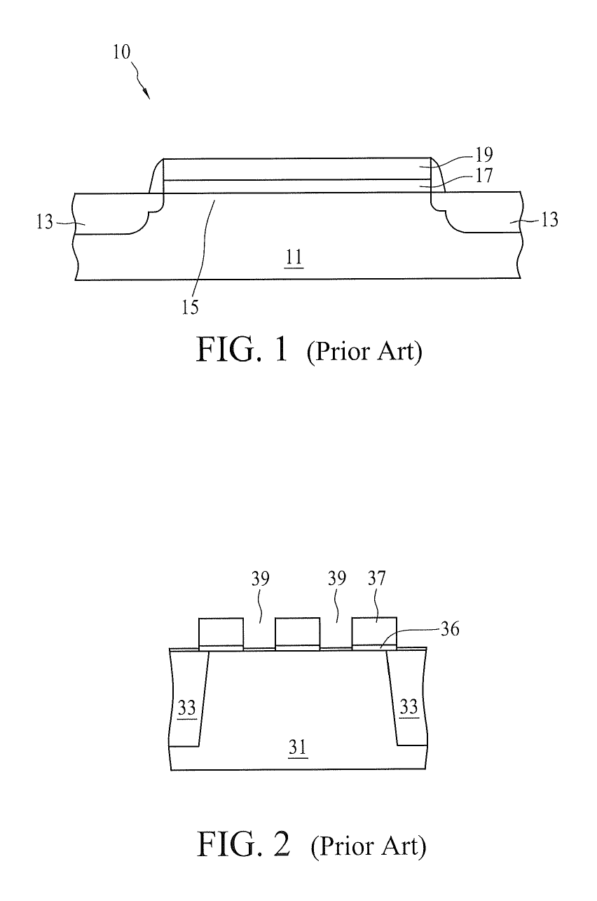

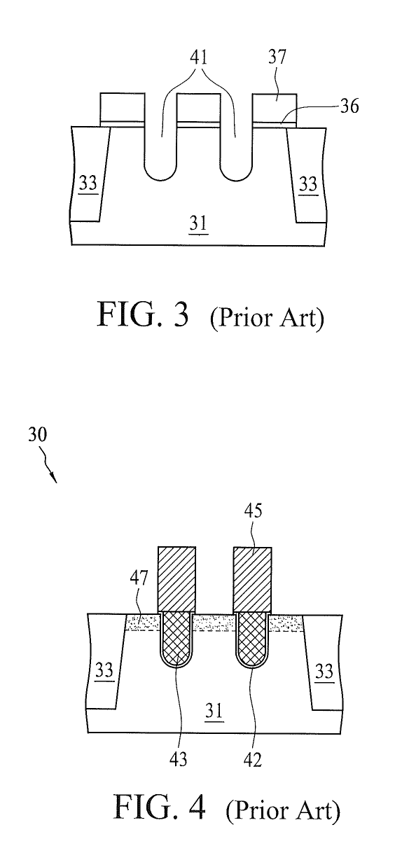

### DETAILED DESCRIPTION

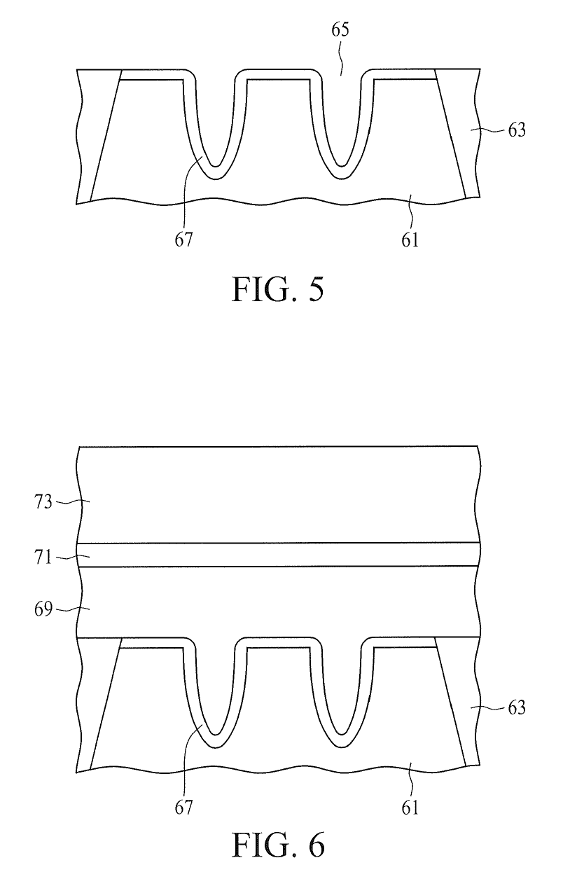

FIG. 5 to FIG. 11 are cross-sectional views showing a method for preparing a transistor structure 60 according to one embodiment of the present disclosure. Referring to FIG, 5, in one embodiment of the present disclosure, fabrication processes are performed to form recesses 65 in a semiconductor substrate 61 such as a silicon substrate having a shallow trench isolation 63. A thermal oxidation process is then performed to form a gate dielectric layer 67 on the surface of the semiconductor substrate 61.

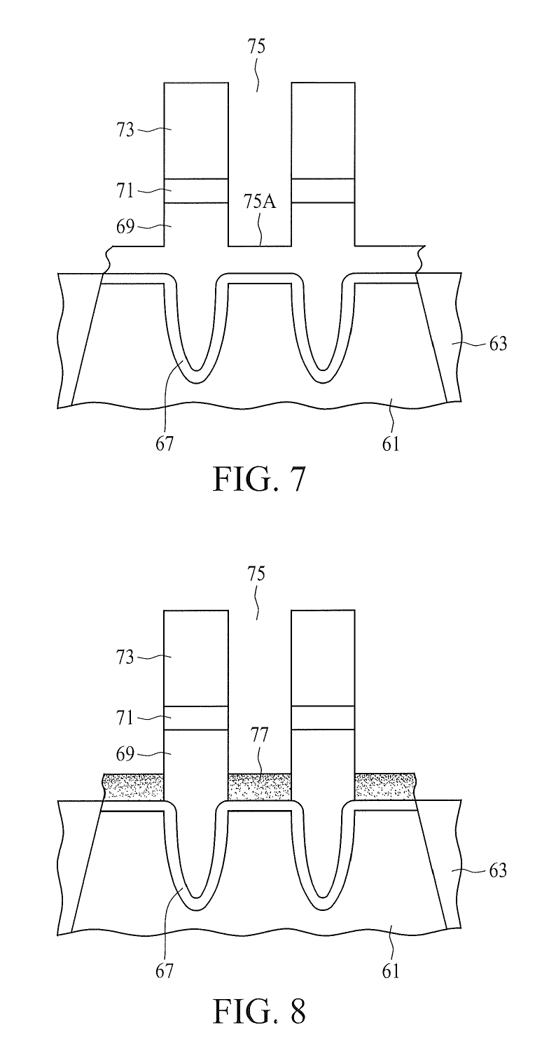

Referring to FIG. 6, deposition processes are performed to form a first conductive layer 69 such as the polysilicon layer on the semiconductor substrate 61 and filling the recess 65; a second conductive layer 71 such as a metal layer on the first conductive layer 69; and a cap layer 73 such as a silicon nitride layer on the second conductive layer 71. Subsequently, an etching process is performed to form a depression 75 through the cap layer 73, the second conductive layer 71, and stops in the first conductive layer 69, wherein the depression 75 comprises a bottom 75A in the first conductive layer 69, as shown in FIG. 7.

Referring to FIG. 8, an implanting process is performed through the depression 75 to convert a portion of the first conductive layer 69 into an implanting region 77 under the depression 75. In one embodiment of the present invention, the implanting process is performed to implant dopants into the first conductive layer 69, wherein the dopants comprise fluorine implanted with energy in the range of 2 KeV to 10 KeV, with a dose in the range of 3E15 cm⁻² to 3E16 cm⁻²,

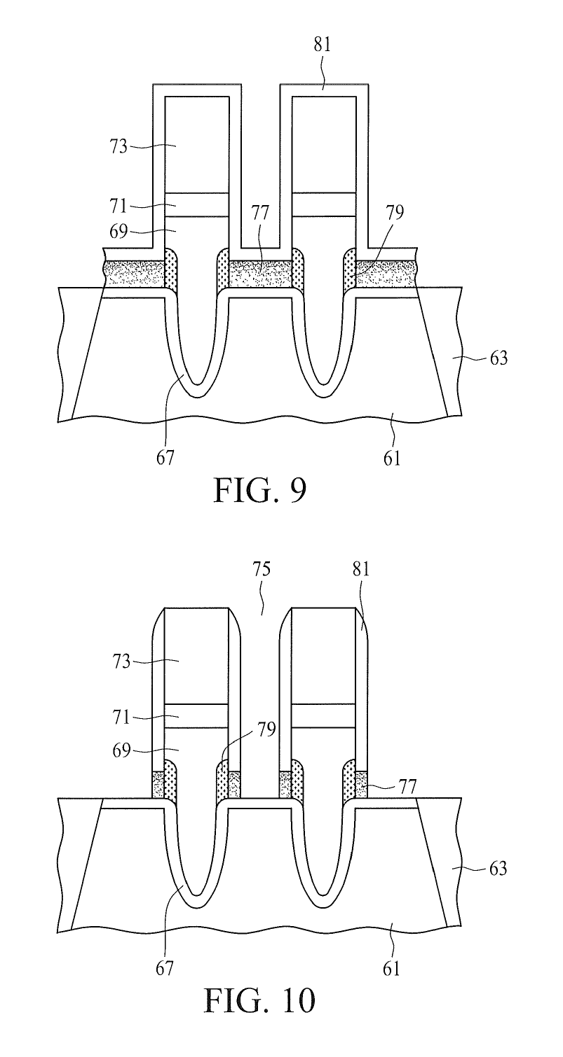

Referring to FIG. 9, a deposition process is performed to form a silicon liner 81 such as a silicon nitride layer on sidewalls of the metal layer and the cap layer. In particular, the liner layer 81 covers the sidewalls of the first conductive layer 69 and the second conductive layer. The liner layer 81 also covers the sidewalls and top surface of the cap layer 73. The deposition process serves as a thermal treating process to form a diffused region 79 adjacent to the implanting region 77.

Referring to FIG. 10, an etching process such as the spacer etching process is performed to remove a portion of the liner layer 81 and the implanting region 77 through the depression 75, while the diffused region 79 is maintained.

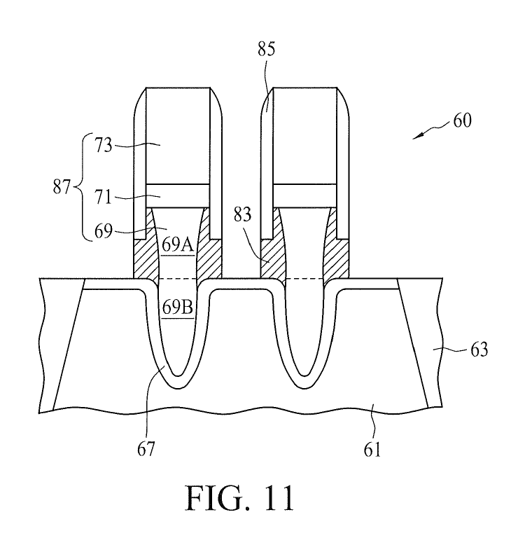

Referring to FIG. 11, an oxidation process is performed to convert the diffused region 79 and the implanting region 77 into a lower insulation layer 83, while the remaining liner layer 81 serves as an upper insulation layer 85 for the gate stack 87. In particular, the diffused fluorine in the first conductive layer 69 can increase the oxidation rate of silicon such that the upper insulation layer (silicon nitride) 85 and the lower insulation layer (silicon oxide) 83 have different thicknesses; for example, the thickness of the upper insulation layer 85 is less than the thickness of the lower insulation layer 83. Furthermore, the diffused fluorine can also induce slight oxidation at the corner of the silicon substrate 61 to improve the interface quality of the gate dielectric layer 67.

In particular, the first conductive layer 69 in FIG. 11 can be considered as a conductor having a lower block 69B within the semiconductor substrate 61 and an upper block 69A without the semiconductor substrate 61. In one embodiment of the present invention, the metal layer 71 and the upper block 69A have different thicknesses; for example, the thickness of the upper block 69A is greater than the thickness of the metal layer 71. In one embodiment of the present invention, the cap layer 73 and the upper block 69A have different thicknesses; for example, the thickness of the upper block 69A is less than the thickness of the cap layer 73.

Although the present disclosure and its objectives have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A transistor, comprising:
a semiconductor substrate;
a conductor having a lower block within the semiconductor substrate and an upper block without the semiconductor substrate;
a metal layer on the upper block;
a cap layer on the metal layer;
an upper insulation layer positioned at least on sidewalls of the metal layer and the cap layer; and
a lower insulation layer positioned on sidewalls of the upper block of the conductor;
wherein the lower insulation layer comprises an upper portion positioned below the metal layer, and the upper portion is between the upper block and a lower portion of the upper insulation layer;
wherein the lower insulation layer comprises fluorine.

2. The transistor structure of claim 1, wherein the upper insulation layer and the lower insulation layer are made of different materials.

3. The transistor structure of claim 1, wherein the lower insulation layer comprises silicon oxide.

4. The transistor structure of claim 1, wherein the upper insulation layer comprises silicon nitride.

5. The transistor structure of claim 1, wherein the upper insulation layer and the lower insulation layer have different thicknesses.

6. The transistor structure of claim 5, wherein the thickness of the upper insulation layer is less than the thickness of the lower insulation layer.

7. The transistor structure of claim 1, wherein the metal layer and the upper block have different thicknesses.

8. The transistor structure of claim 7, wherein the thickness of the upper block is greater than the thickness of the metal layer.

9. The transistor structure of claim 1, wherein the cap layer and the upper block have different thicknesses.

10. The transistor structure of claim 9, wherein the thickness of the upper block is less than the thickness of the cap layer.

11-17. (canceled)
